(19) United States
(12) Patent Application Publication
(10) Pub. No.: US 2011/0168552 A1
(43) Pub. Date: Jul. 14, 2011

(54) SYSTEM FOR SPUTTERING DEPOSITION

(75) Inventor: HSIN-CHIN HUNG, Tu-Cheng (TW)

(73) Assignee: HON HAI PRECISION INDUSTRY CO., LTD., Tu-Cheng (TW)

(21) Appl. No.: 12/846,809

(22) Filed: Jul. 29, 2010

(30) Foreign Application Priority Data
Jan. 11, 2010 (TW) 99100567

(51) Int. Cl. C23C 14/34

(52) U.S. Cl. 204/298.03; 204/298.07

(57) ABSTRACT

An exemplary system for sputtering deposition includes a sputtering chamber and a gas supplying system. The sputtering chamber includes a first sputtering space and a second sputtering space isolated from the first sputtering space. Each of the first and second sputtering spaces is configured for receiving a target and a substrate therein. The gas supplying system includes a reactive gas source, an inert gas source, a first chamber in communication with the reactive gas source and the inert gas source, and a second chamber in communication with the inert gas source. Both the first and second chambers are in communication with the first and second sputtering spaces through valves.

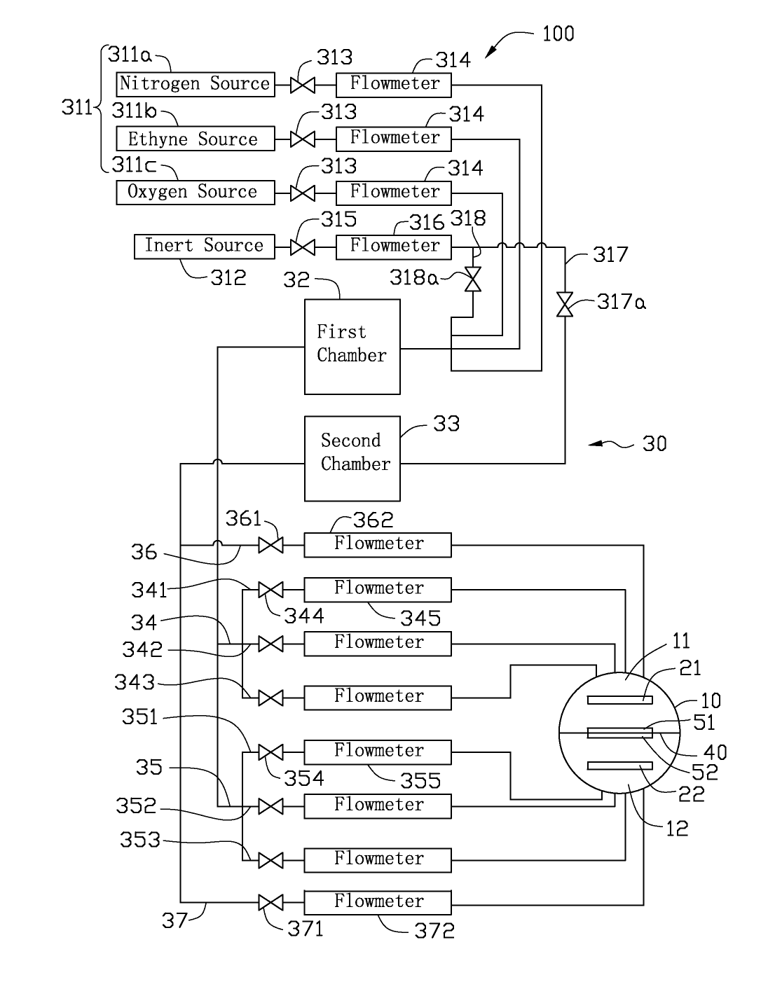

### BACKGROUND

1. Technical Field

The present disclosure relates to a system for sputtering deposition.

2. Description of Related Art

Sputtering deposition is a physical vapor deposition (PVD) method of depositing thin films by sputtering, that is ejecting material from a target acting as a source, which then deposits onto a substrate, such as a silicon wafer.

A typical reaction sputtering deposition uses reactive gases such as O₂ to react with the material from a target during the sputtering deposition, and then form a reaction compound film on the substrate. During the sputtering deposition, an inert gas is usually added to act as a working gas for forming a plasma area between the target and the substrate. After the reaction sputtering deposition, the target usually has some reaction compound particles remaining on the surface, thus cleaning the target is needed. An inert gas can be used in the cleaning of the target, however, if the inert gas flow has the same passage as the reactive gases did, remnant reactive gases in the passage would cause additional contamination to the target. Furthermore, if sputtering deposition and the cleaning of the target uses the same inert gas, the sputtering deposition cannot be carried out during the cleaning of the target, resulting in reduced efficiency.

What is needed, therefore, is a system for sputtering deposition which can overcome the above shortcomings.

### BRIEF DESCRIPTION OF THE DRAWING

Many aspects of the present system for sputtering deposition can be better understood with reference to the following drawings. The components in the drawings are not necessarily drawn to scale, the emphasis instead being placed upon clearly illustrating the principles of the present system. Moreover, in the drawing, like reference numerals designate corresponding parts throughout the several views.

The drawing is a block diagram of a system for sputtering deposition in accordance with an embodiment.

### DETAILED DESCRIPTION

Embodiment of the present system for sputtering deposition will now be described in detail below and with reference to the drawing.

Referring to the drawing, an exemplary system 100 for sputtering deposition in accordance with an embodiment, is provided. The system 100 includes a sputtering chamber 10, a first target 21, a second target 22, a gas supplying system 30, and an isolating board 40.

The isolating board 40 completely isolates the sputtering chamber 10 into a first sputtering space 11 and a second sputtering space 12. The first and second targets 21, 22 are arranged in the first sputtering space 11 and the second sputtering space 12 and face opposite sides of the isolating board 40. Substrates 51, 52 to be deposited may be mounted on the opposite sides of the isolating board 40. During deposition, voltages are applied between the substrates and the corresponding first and second targets 21, 22. The first and second targets 21, 22 configured as cathodes in the first and second sputtering spaces, respectively, and the substrates configured as anodes in the first and second sputtering spaces, respectively.

The gas supplying system 30 includes reactive gas sources 311, an inert gas source 312, a first chamber 32, a second chamber 33, a first passage 34, a second passage 35, a third passage 36 and a fourth passage 37. The reactive gas sources 311 include a nitrogen (N₂) source 311a, ethyne (C₂H₂) source 311b, oxygen (O₂) source 311c. The nitrogen source 311a, ethyne source 311b, oxygen source 311c are in communication with the first chamber 32 each via a valve 313 and a flowmeter 314. The inert gas source 312 may be an argon (Ar) source and is in communication with two channels 317, 318 through a common valve 315 and a common flowmeter 316. The channels 317, 318 extend to the first chamber 32 and the second chamber 33 through valves 317a, 318a, respectively. The first chamber 32 is used to mix the incoming gases and the second chamber 33 can act as a buffer.

The first and second passages 34, 35 are in communication with the first chamber 32, and the third and fourth passages 36, 37 are in communication with the second chamber 33. The first passage 34 has three channels 341, 342 and 343 extending to different areas of the first sputtering space 11 each via a valve 344 and a flowmeter 345. The second passage 35 has three channels 351, 352 and 353 extending to different areas of the second sputtering space 12 each through a valve 354 and a flowmeter 355. The third passage 36 extends to the first sputtering space 11 through a valve 361 and a flowmeter 362. The fourth passage 37 extends to the second sputtering space 12 through a valve 371 and a flowmeter 372.

In application, the first sputtering space 11 and the second sputtering space 12 can be used independently. The first chamber 32 cooperates with the valves 313, 318a can supply the first sputtering space 11 and the second sputtering space 12 one or more gases needed in the sputtering deposition. The inert gas comes from the first chamber 32 can act as a working gas which can form plasma areas between the targets 21, 22 and the corresponding substrates, and can independently cause the sputtering deposition or improve the reaction sputtering deposition with the reactive gases. The gases bombard the targets 21, 22 under the voltages, respectively, and then the materials (atoms) of the targets 21, 22 or the reaction compounds of the materials of the targets 21, 22 and the reactive gases are sputtered and deposited on the substrates on the isolating board 40.

The second chamber 33 supplies the inert gas to the first sputtering space 11 and the second sputtering space 12. The inert gas comes from the second chamber 33 is independently used to blow away material particles sticking on surfaces of the first and second targets 21, 22, thus cleaning the first and second targets 21, 22. The inert gas in the second chamber 33 does not mix with the reactive gases in the first chamber 32, thus the cleaning result of the targets 21, 22 can be better without any reaction. In particular, when the sputtering deposition in one or both of the first and second sputtering spaces 11, 12 stops, the cleaning of the corresponding targets 21, 22 can start. Due to the valves 317a, 318a, the sputtering deposition and the cleaning may be done simultaneously. Efficiency of the entire system 100 for sputtering deposition is thus improved. The sputtering deposition and the cleaning of the targets 21, 22 in the first and second sputtering spaces 11, 12 use the same inert gas source 312, thus the system 100 can be more compact.

It is understood that the above-described embodiment are intended to illustrate rather than limit the disclosure. Variations may be made to the embodiment and methods without departing from the spirit of the disclosure. Accordingly, it is appropriate that the appended claims be construed broadly and in a manner consistent with the scope of the disclosure.

What is claimed is:

1. A system for sputtering deposition, the system comprising:
a sputtering chamber comprising a first sputtering space and a second sputtering space isolated from the first sputtering space, each of the first and second sputtering spaces configured for receiving a target and a substrate therein; and
a gas supplying system comprising a reactive gas source, an inert gas source, a first chamber in communication with the reactive gas source and the inert gas source, and a second chamber in communication with the inert gas source, both the first and second chamber being in communication with the first and second sputtering spaces.

2. The system of claim 1, wherein the reactive gas source comprises a nitrogen source, an ethyne source, an oxygen source, three valves for respectively controlling flowing of gases from the nitrogen source, the ethyne source, and the oxygen source to the first chamber, and three flowmeters for displaying flow rate of the gases from the nitrogen source, the ethyne source, and the oxygen source to the first chamber.

3. The system of claim 1, wherein the first chamber is configured to mix gases from the reactive gas source and the inert gas source.

4. The system of claim 1, wherein the inert gas source comprises an argon source, and two valves for respectively controlling flowing of argon gas from the argon source to the first chamber and the second chamber.

5. The system of claim 1, wherein the gas supplying system comprises three first channels connecting the first chamber to the first sputtering space, and three second channels connecting the first chamber to the second sputtering space.

6. The system of claim 5, wherein a valve and a flowmeter are arranged on each of the first and second channels.

7. The system of claim 1, wherein the gas supplying system includes two third channels respectively connecting the first and second sputtering spaces to the second chamber, and a valve and a flowmeter arranged on each of the third channels.

8. The system of claim 1, wherein the sputtering chamber comprises an isolating board mounted therein for isolating the first and second sputtering spaces, the isolating board comprises a first surface facing the first sputtering space and an opposite second surface facing the second sputtering space, the substrates are arranged on the first and second surfaces.

9. The system of claim 8, wherein the targets face the respective substrates and are spaced a distance apart from the respective substrates.
